(19) United States
(12) Patent Application Publication
(10) Pub. No.: US 2023/0191553 A1
(43) Pub. Date: Jun. 22, 2023

(54) METHOD OF RAISING POLISHING HEAD AFTER POLISHING OF WORKPIECE, POLISHING APPARATUS FOR WORKPIECE, AND COMPUTER-READABLE STORAGE MEDIUM STORING PROGRAM

(71) Applicant: EBARA CORPORATION, Tokyo (JP)

(72) Inventors: Yuichi KATO, Tokyo (JP); Osamu NABEYA, Tokyo (JP)

(21) Appl. No.: 18/080,252

(22) Filed: Dec. 13, 2022

(30) Foreign Application Priority Data
Dec. 20, 2021 (JP) 2021-205715

(51) Int. Cl. B24B 37/005; B24B 37/32

(52) U.S. Cl. CPC B24B 37/005; B24B 37/32

(57) ABSTRACT

A method of raising a polishing head capable of preventing a workpiece from bending and preventing an excessive stress from generating in the workpiece by avoiding contact between the workpiece and a retainer ring when the polishing head is raised from a polishing pad after polishing of the workpiece is disclosed. The method includes: polishing the workpiece by pressing the workpiece against the polishing pad while rotating the polishing head and the polishing pad; stopping the rotations of the polishing pad and the polishing head; raising the retainer ring of the polishing head relative to the workpiece to separate the retainer ring from the polishing pad and moving the retainer ring to a position higher than the workpiece; and then raising the polishing head with the workpiece held on the polishing head.

### CROSS REFERENCE TO RELATED APPLICATION

This application claims priority to Japanese Patent Application No. 2021-205715 filed Dec. 20, 2021, the entire contents of which are hereby incorporated by reference.

### BACKGROUND

Chemical mechanical polishing (CMP) is a technique of polishing a workpiece by bringing the workpiece into sliding contact with a polishing surface of a polishing pad while supplying a polishing liquid containing abrasive grains, such as silica (SiO2), onto the polishing surface. As shown in FIG. 13, a polishing apparatus for performing CMP includes a polishing table 501 that supports a polishing pad 500, a polishing head 505 configured to hold a workpiece W, and a polishing-liquid nozzle 508 configured to supply a polishing liquid onto the polishing pad 500.

Polishing of the workpiece W using such a polishing apparatus is performed as follows. While the polishing table 501 is rotated together with the polishing pad 500, the polishing liquid is supplied onto the polishing pad 500 from the polishing-liquid nozzle 508. The polishing head 505 rotates the workpiece W and presses the workpiece W against the polishing pad 500. While the workpiece W is in sliding contact with the polishing pad 500 in the presence of the polishing liquid, a surface of the workpiece W is planarized by a combination of a chemical action of the polishing liquid and a mechanical action of the polishing pad 500 and abrasive grains contained in the polishing liquid.

During polishing of the workpiece W, the surface of the workpiece W is placed in sliding contact with the rotating polishing pad 500, so that a frictional force acts on the workpiece W. Therefore, the polishing head 505 is provided with a retainer ring 510 in order to prevent the workpiece W from coming off the polishing head 505 when the workpiece W is being polished. The retainer ring 510 is arranged so as to surround the workpiece W, and the retainer ring 510 presses the polishing pad 500 outside the workpiece W while the retainer ring 510 is rotating during polishing of the workpiece W.

FIG. 14 is a cross-sectional view showing part of the polishing head 505 shown in FIG. 13. As shown in FIG. 14, the polishing head 505 has an annular elastic membrane 512 for pressing the retainer ring 510 against the polishing pad 500. A pressure chamber 513 is formed inside the elastic membrane 512. When pressurized gas (for example, pressurized air) is supplied into the pressure chamber 513, the elastic membrane 512 that receives the fluid pressure in the pressure chamber 513 presses the retainer ring 510 against the polishing pad 500. Therefore, during polishing of the workpiece W, the retainer ring 510 can prevent the workpiece W from coming off the polishing head 505.

The polishing head 505 further has an elastic membrane 514 for pressing the workpiece W against the polishing pad 500. Pressure chambers 515 are formed inside the elastic membrane 514. When pressurized gas (for example, pressurized air) is supplied into the pressure chambers 515, the elastic membrane 514 under the fluid pressure in the pressure chambers 515 presses the workpiece W against the polishing pad 500. Therefore, the workpiece W is rubbed against the polishing pad 500 in the presence of the polishing liquid on the polishing pad 500.

Both the elastic membrane 512 and the elastic membrane 514 are fixed to a carrier 517 of the polishing head 505. The retainer ring 510 is configured to be vertically movable relative to the carrier 517 and the elastic membrane 514 so as to allow the retainer ring 510 to press the polishing pad 500 independently of the workpiece W.

After polishing of the workpiece W, as shown in FIG. 15, negative pressure is formed in the pressure chambers 515 so that the workpiece W is attracted to the elastic membrane 514. When the workpiece W is attracted to the elastic membrane 514, the workpiece W is slightly pulled up. If a surface tension of the liquid that exists between the workpiece W and the polishing pad 500 is high, pulling the workpiece W off the polishing pad 500 may fail. Therefore, in order to reduce the surface tension acting between the workpiece W and the polishing pad 500, the polishing head 505 and the polishing pad 500 are rotated when the workpiece W is being attracted to the elastic membrane 514. Thereafter, the polishing head 505 is elevated together with the workpiece W, and further moved together with the workpiece W to a predetermined workpiece transfer position.

The retainer ring 510 is kept pressing the polishing pad 500 in order to prevent the workpiece W on the rotating polishing pad 500 from coming off the polishing head 505 even when the polishing head 505 is being raised. Thus, as shown in FIG. 16, the carrier 517 of the polishing head 505 and the workpiece W are raised away from the polishing pad 500 while a lower surface of the retainer ring 510 remains in contact with the polishing pad 500.

However, when the workpiece W is being raised while the workpiece W is in contact with an inner surface of the retainer ring 510, the workpiece W may bend downward and an excessive stress may be generated in the workpiece W since a portion of the workpiece W that is in contact with the inner surface of the retainer ring 510 is forced to remain on the polishing pad 500. If this stress is too large, the workpiece W may crack. In particular, as shown in FIG. 17, when a wear groove 510a is formed in the inner surface of the retainer ring 510 due to the contact with the workpiece W, the workpiece W is more likely to be caught by the retainer ring 510, and the workpiece W is more likely to bend downward. As a result, the workpiece W may crack.

### SUMMARY

Therefore, there is provided a method of raising a polishing head capable of preventing a workpiece from bending and preventing an excessive stress from generating in the workpiece by avoiding contact between the workpiece and an inner surface of a retainer ring when the polishing head is raised from a polishing pad after polishing of the workpiece. There is also provided a workpiece polishing apparatus capable of carrying out such a method. Furthermore, there is provided a computer-readable storage medium storing a program for executing such a method.

Embodiments, which will be described below, relate to a technique of reducing a stress on a workpiece after polishing of the workpiece and raising a polishing head together with the workpiece, such as wafer, substrate, panel, etc., used in manufacture of semiconductor devices.

In an embodiment, there is provided a method of raising a polishing head after polishing of a workpiece, comprising: polishing the workpiece by pressing the workpiece against a polishing pad while rotating the polishing head and the polishing pad; stopping the rotations of the polishing pad and the polishing head; raising a retainer ring of the polishing head relative to the workpiece to separate the retainer ring from the polishing pad and moving the retainer ring to a position higher than the workpiece; and then raising the polishing head with the workpiece held on the polishing head.

In an embodiment, the method further comprises holding the workpiece by the polishing head after polishing of the workpiece and before raising of the polishing head.

In an embodiment, raising the retainer ring to the position higher than the workpiece is performed before or simultaneously with holding the workpiece by the polishing head.

In an embodiment, holding the workpiece by the polishing head is performed while supplying fluid directly to an area between the workpiece and the polishing pad.

In an embodiment, the polishing head includes an elastic membrane forming a plurality of pressure chambers for pressing the workpiece against the polishing pad, holding the workpiece by the polishing head comprises holding the workpiece with the polishing head by forming a negative pressure in an outer pressure chamber of the plurality of pressure chambers and then forming a negative pressure in an inner pressure chamber of the plurality of pressure chambers.

In an embodiment, holding the workpiece by the polishing head is performed before stopping the rotations of the polishing pad and the polishing head.

In an embodiment, raising the polishing head comprises: raising the polishing head at a first speed until the entire workpiece is separated from the polishing pad; and raising the polishing head at a second speed higher than the first speed after the entire workpiece is separated from the polishing pad.

In an embodiment, there is provided a polishing apparatus for a workpiece, comprising: a polishing table configured to support a polishing pad; a polishing-table rotating device configured to rotate the polishing table together with the polishing pad; a polishing head configured to press the workpiece against the polishing pad to polish the workpiece; a polishing-head pressure controller configured to control pressure in the polishing head; a polishing-head rotating device configured to rotate the polishing head; a polishing-head elevating device configured to raise and lower the polishing head relative to the polishing table; and an operation controller configured to control operations of the polishing-table rotating device, the polishing-head pressure controller, the polishing-head rotating device, and the polishing-head elevating device, the polishing head having a retainer ring surrounding the workpiece, the operation controller being configured to: after polishing of the workpiece, instruct the polishing-table rotating device and the polishing-head rotating device to stop rotations of the polishing pad and the polishing head; instruct the polishing-head pressure controller to raise the retainer ring relative to the workpiece to separate the retainer ring from the polishing pad and move the retainer ring to a position higher than the workpiece; and then instruct the polishing-head elevating device to raise the polishing head with the workpiece held on the polishing head.

In an embodiment, the operation controller is configured to instruct the polishing-head pressure controller to cause the polishing head to hold the workpiece after the workpiece is polished and before the polishing head is raised.

In an embodiment, the operation controller is configured to instruct the polishing-head pressure controller to raise the retainer ring to the position higher than the workpiece before or simultaneously with the workpiece is held by the polishing head.

In an embodiment, the polishing apparatus further comprises a fluid supply system configured to supply fluid to an area between the workpiece and the polishing pad, the operation controller being configured to instruct the fluid supply system to supply the fluid directly to the area between the workpiece and the polishing pad when the polishing head holds the workpiece.

In an embodiment, the polishing head includes an elastic membrane forming a plurality of pressure chambers for pressing the workpiece against the polishing pad, and the operation controller is configured to instruct the polishing-head pressure controller to cause the polishing head to hold the workpiece by forming a negative pressure in an outer pressure chamber of the plurality of pressure chambers and then forming a negative pressure in an inner pressure chamber of the plurality of pressure chambers.

In an embodiment, the operation controller is configured to instruct the polishing-head pressure controller to cause the polishing head to hold the workpiece before rotations of the polishing pad and the polishing head are stopped.

In an embodiment, the operation controller is configured to instruct the polishing-head elevating device to raise the polishing head at a first speed until the entire workpiece is separated from the polishing pad, and raise the polishing head at a second speed higher than the first speed after the entire workpiece is separated from the polishing pad.

In an embodiment, there is provided a computer-readable storage medium storing a program for causing a computer to: instruct a polishing-head pressure controller, a polishing-table rotating device, and a polishing-head rotating device to polish a workpiece by pressing the workpiece against a polishing pad while rotating a polishing head and the polishing pad on a polishing table; after polishing of the workpiece, instruct the polishing-table rotating device and the polishing-head rotating device to stop the rotations of the polishing pad and the polishing head; instruct the polishing-head pressure controller to raise a retainer ring of the polishing head relative to the workpiece to separate the retainer ring from the polishing pad and move the retainer ring to a position higher that the workpiece; and instruct the polishing-head elevating device to raise the polishing head with the workpiece held on the polishing head.

According to the above-described embodiments, the retainer ring is raised higher than the workpiece prior to raising of the polishing head. Therefore, when the polishing head is raised, the workpiece does not come into contact with the retainer ring, and the workpiece is not bent downward by the retainer ring. As a result, an excessive stress is not generated in the workpiece, and cracking of the workpiece can be prevented.

### BRIEF DESCRIPTION OF THE DRAWINGS

FIG. 1 is a schematic diagram showing one embodiment of a polishing apparatus;

FIG. 2 is a cross-sectional view showing one embodiment of a polishing head;

FIG. 3 is a diagram explaining a manner in which a first elastic membrane of the polishing head holds a workpiece by vacuum suction;

FIG. 4 is a diagram illustrating a manner in which a retainer ring is raised relative to the workpiece and separated from the polishing pad;

FIG. 5 is a diagram illustrating a manner in which the polished workpiece is released from the polishing head;

FIG. 6 is a flow chart describing one embodiment of operations of the polishing head during and after polishing of a workpiece;

FIG. 7 is a flow chart describing another embodiment of operations of the polishing head during and after polishing of a workpiece;

FIG. 8 is a schematic diagram showing an example of operations of the polishing head when holding a workpiece;

FIG. 9 is a schematic diagram showing another example of operations of the polishing head when holding a workpiece;

FIG. 10 is a diagram illustrating an embodiment of supplying fluid between a workpiece and the polishing pad when the polishing head is holding the workpiece;

FIGS. 11A and 11B are schematic diagrams illustrating an embodiment in which a raising speed of the polishing head is switched from a first speed to a second speed;

FIGS. 12A and 12B are plan views illustrating still another embodiment of operations of the polishing head after polishing of a workpiece;

FIG. 13 is a schematic diagram showing a conventional polishing apparatus;

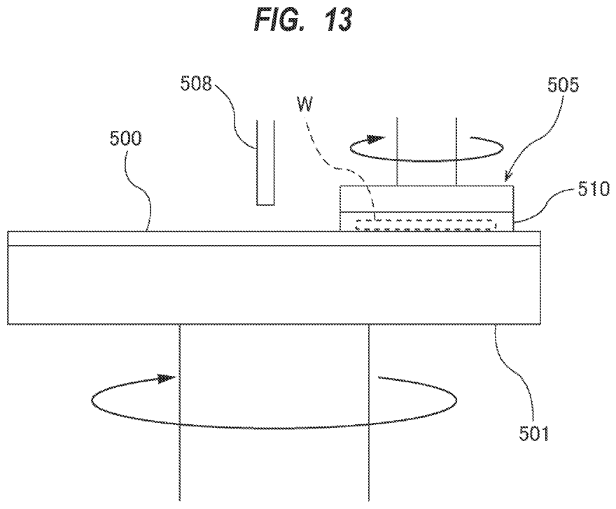

FIG. 14 is a cross-sectional view showing part of a polishing head shown in FIG. 13;

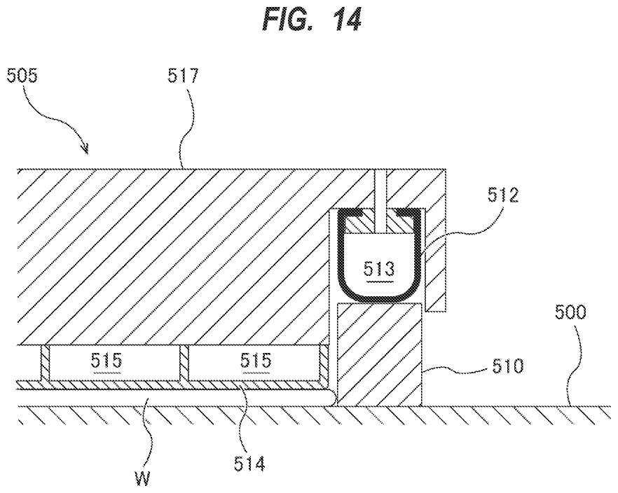

FIG. 15 is a diagram illustrating a manner in which the conventional polishing head holds a workpiece;

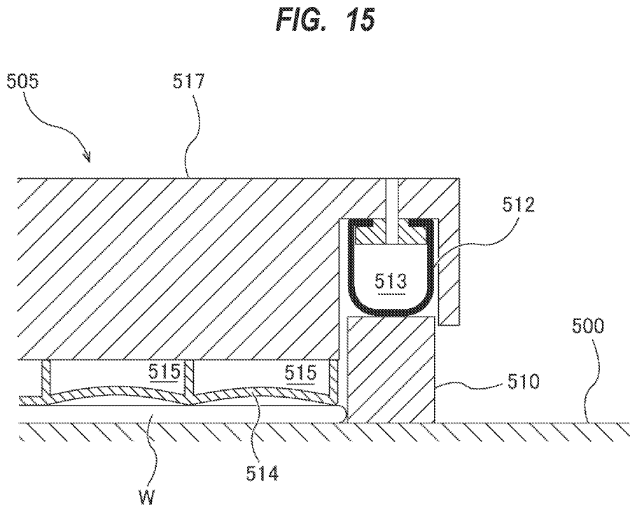

FIG. 16 is a diagram illustrating how the workpiece bends downward as the polishing head rises; and

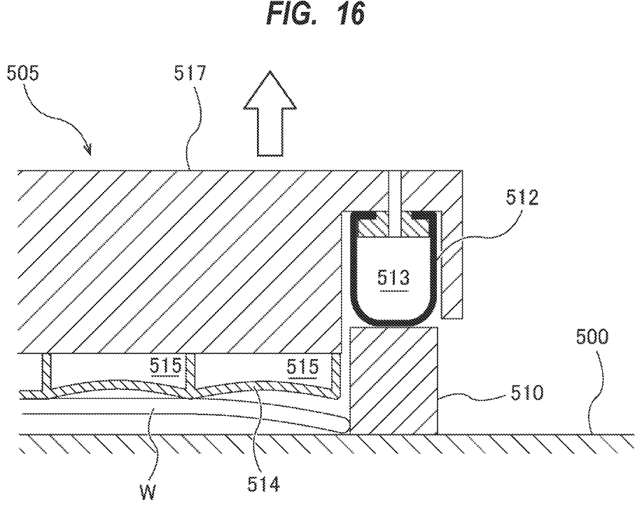

FIG. 17 is a diagram illustrating how the workpiece bends downward as the polishing head rises.

### DESCRIPTION OF EMBODIMENTS

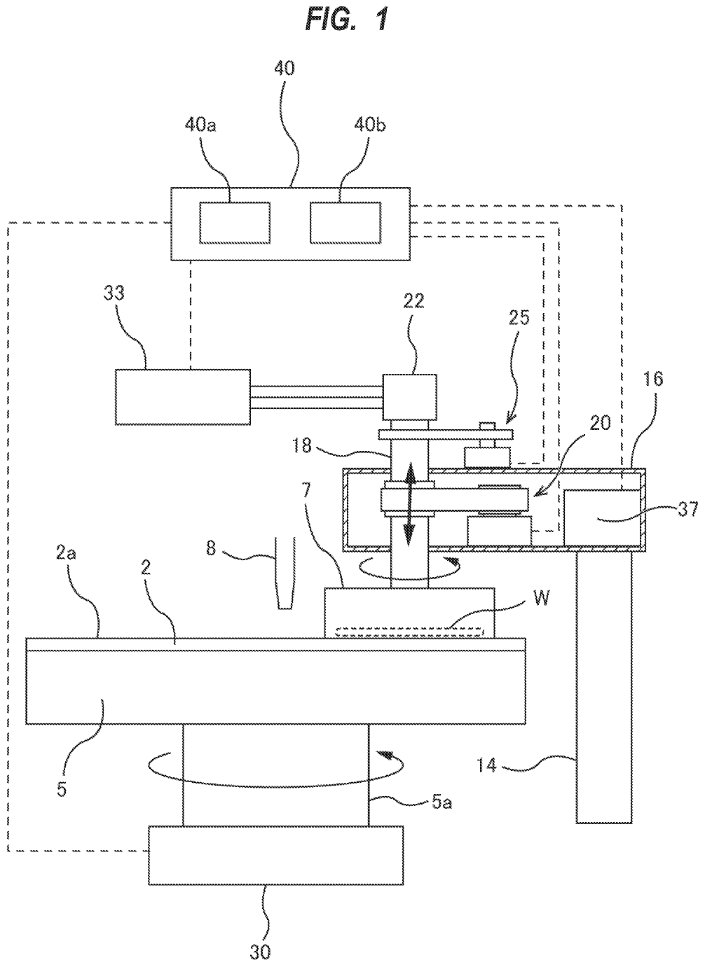

Hereinafter, embodiments will be described with reference to the drawings. FIG. 1 is a schematic diagram showing one embodiment of a polishing apparatus. The polishing apparatus is an apparatus that chemically and mechanically polishes a workpiece W, such as wafer, substrate (e.g., circular substrate, rectangular substrate), or panel, used in manufacture of semiconductor devices. In the embodiment shown in FIG. 1, the workpiece W is a wafer.

As shown in FIG. 1, this polishing apparatus includes a polishing table 5 that supports a polishing pad 2 having a polishing surface 2a, a polishing head 7 configured to press the workpiece W against the polishing surface 2a, and a polishing-liquid supply nozzle 8 configured to supply a polishing liquid (e.g., slurry containing abrasive grains) onto the polishing surface 2a. The polishing head 7 is configured to be able to hold the workpiece W on its lower surface.

The polishing apparatus further includes a support shaft 14, a polishing-head oscillation arm 16 coupled to an upper end of the support shaft 14, a polishing-head shaft 18 rotatably supported by a free end of the polishing-head oscillation arm 16, and a polishing-head rotating device 20 configured to rotate the polishing-head shaft 18 and the polishing head 7. The polishing head 7 is fixed to a lower end of the polishing-head shaft 18. The polishing-head rotating device 20 is fixed to the polishing-head oscillation arm 16. The polishing-head rotating device 20 includes an electric motor, a torque transmission device, etc., but the configuration thereof is not particularly limited. The polishing-head rotating device 20 is coupled to the polishing-head shaft 18 and configured to rotate the polishing-head shaft 18 and the polishing head 7 in a direction indicated by arrow. A rotary joint 22 is coupled to an upper end of the polishing-head shaft 18.

The polishing apparatus further includes a polishing-head elevating device 25 configured to move the polishing head 7 and the polishing-head shaft 18 up and down relative to the polishing table 5 and the polishing-head oscillation arm 16. The polishing-head elevating device 25 may have a combination of a ball screw mechanism and a servomotor, or an actuator (e.g., an air cylinder), but the configuration of the polishing-head elevating device 25 is not particularly limited. When the polishing-head elevating device 25 moves the polishing-head shaft 18 vertically relative to the polishing-head oscillation arm 16, the polishing head 7 moves up and down relative to the polishing-head oscillation arm 16 and the polishing table 5 as indicated by arrows.

The polishing apparatus further includes a polishing-table rotating device 30 configured to rotate the polishing pad 2 and the polishing table 5 about their own axes. The polishing-table rotating device 30 is arranged below the polishing table 5, and the polishing table 5 is coupled to the polishing-table rotating device 30 via a table shaft 5a. The polishing-table rotating device 30 includes an actuator, such as an electric motor, but its configuration is not particularly limited. The polishing table 5 and the polishing pad 2 are integrally rotated about the table shaft 5a in a direction indicated by arrow by the polishing-table rotating device 30. The polishing pad 2 is attached to an upper surface of the polishing table 5. An exposed surface of the polishing pad 2 constitutes the polishing surface 2a for polishing the workpiece W, such as wafer.

The polishing apparatus further includes a polishing-head pressure controller 33 configured to control pressure inside the polishing head 7. The polishing-head pressure controller 33 is configured to operate components of the polishing head 7 (for example, a retainer ring and an elastic membrane, which will be described later). In this embodiment, the polishing-head pressure controller 33 includes pressure regulators (not shown) configured to regulate pressures of gas (e.g., air) as working fluid for operating the components of the polishing head 7. For example, the pressure regulator regulates the pressure of the gas supplied into the polishing head 7 to thereby regulate a force of the polishing head 7 for pressing the workpiece W against the polishing pad 2. The polishing-head pressure controller 33 is coupled to the rotary joint 22 and supplies the gas of a predetermined pressure to the polishing head 7 through the rotary joint 22.

The polishing apparatus further includes a polishing-head moving device 37 configured to move the polishing head 7 in a direction parallel to the polishing surface 2a of the polishing pad 2. The polishing-head moving device 37 is fixed to the upper end of the support shaft 14 and coupled to the polishing-head oscillation arm 16. The polishing-head moving device 37 rotates the polishing-head oscillation arm 16 around the support shaft 14 to move the polishing head 7, supported by the polishing-head oscillation arm 16, in a direction parallel to the polishing surface 2a of the polishing pad 2. It should be noted, however, that the configuration of the polishing-head moving device 37 is not limited to this embodiment. In one embodiment, the polishing-head moving device 37 may be coupled to a lower part of the support shaft 14 and configured to rotate the support shaft 14 and the polishing-head oscillation arm 16 together about the support shaft 14.

The polishing apparatus further includes an operation controller 40 configured to control the operations of the entire polishing apparatus including the polishing-head rotating device 20, the polishing-head elevating device 25, the polishing-table rotating device 30, the polishing-head pressure controller 33, and the polishing-head moving device 37. The operation controller 40 includes at least one computer. The operation controller 40 may include multiple computers. For example, the operation controller 40 may be composed of a combination of an edge server and a cloud server.

The operation controller 40 includes a memory 40a and an arithmetic device 40b. The arithmetic device 40b includes a CPU (Central Processing Unit) or GPU (Graphic Processing Module) configured to perform arithmetic operations according to instructions included in programs stored in the memory 40a. The memory 40a includes a main memory (e.g., random access memory) to which the arithmetic device 40b is accessible and an auxiliary memory (e.g., hard disk drive or solid state drive) for storing data and programs therein. However, the specific configurations of the operation controller 40 are not limited to these examples.

Polishing of the workpiece W is performed as follows. The workpiece W, with its surface, to be polished, facing downward, is held by the polishing head 7. While the polishing head 7 and the polishing table 5 are rotated, the polishing liquid (for example, slurry containing abrasive grains) is supplied onto the polishing surface 2a of the polishing pad 2 from the polishing-liquid supply nozzle 8 provided above the polishing table 5. The polishing pad 2 rotates about its central axis together with the polishing table 5. The polishing head 7 is lowered to a predetermined polishing-operation height by the polishing-head elevating device 25. Further, the polishing head 7 presses the workpiece W against the polishing surface 2a of the polishing pad 2 while the polishing head 7 is maintained at the polishing-operation height. The workpiece W rotates together with the polishing head 7. With the polishing liquid present on the polishing surface 2a of the polishing pad 2, the workpiece W is placed in sliding contact with the polishing surface 2a. The surface of the workpiece W is polished by a combination of a chemical action of the polishing liquid and a mechanical action of the polishing pad 2 and/or the abrasive grains contained in the polishing liquid.

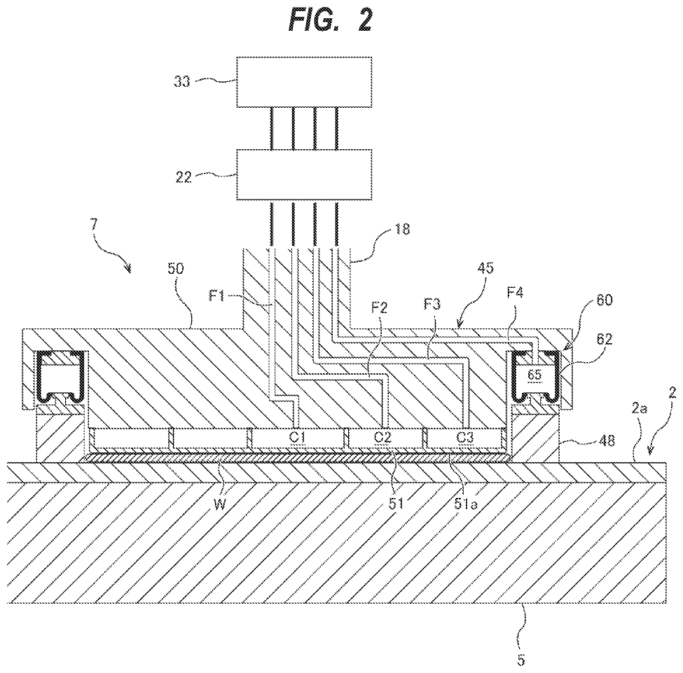

Next, the details of the polishing head 7 will be described. FIG. 2 is a cross-sectional view showing one embodiment of the polishing head 7. The polishing head 7 has a head body 45 and a retainer ring 48. The head body 45 includes a carrier 50 coupled to the polishing-head shaft 18 and a first elastic membrane 51 attached to a lower surface of the carrier 50.

A lower surface of the first elastic membrane 51 constitutes a pressing surface 51a for pressing the workpiece W against the polishing pad 2. The pressing surface 51a is in contact with an upper surface of the workpiece W (i.e., a surface opposite to the surface to be polished). A plurality of first pressure chambers C1, C2, C3 are formed between the carrier 50 and the first elastic membrane 51. Specifically, the plurality of first pressure chambers C1, C2, C3 are formed inside the first elastic membrane 51. The central first pressure chamber C1 is circular, the first pressure chamber C2 outside the first pressure chamber C1 is annular, and the first pressure chamber C3 outside the first pressure chamber C2 is annular. These first pressure chambers C1, C2, C3 are arranged concentrically.

The first pressure chambers C1, C2, C3 are coupled to the polishing-head pressure controller 33 through first fluid lines F1, F2, F3 and the rotary joint 22. The polishing-head pressure controller 33 in this embodiment includes pressure regulators (not shown) configured to supply the gas of predetermined pressure(s) to the polishing head 7. When fluid (e.g., gas, such as air) is supplied to the first pressure chambers C1, C2, C3, the pressing surface 51a of the first elastic membrane 51 that receives the fluid pressure(s) in the first pressure chambers C1, C2, C3 presses the workpiece W against the polishing surface 2a of the polishing pad 2. The number of first pressure chambers C1, C2, C3 is not limited to the embodiment shown in FIG. 2. In one embodiment, a single first pressure chamber may be provided between the carrier 50 and the first elastic membrane 51.

The retainer ring 48 is arranged so as to surround the workpiece W and the first elastic membrane 51. More specifically, the retainer ring 48 is arranged so as to surround the peripheral edge of the workpiece W and the pressing surface 51a of the first elastic membrane 51. An upper portion of the retainer ring 48 is coupled to an annular retainer-ring pressing mechanism 60. This retainer-ring pressing mechanism 60 is configured to apply a uniform downward load to an entire upper surface of the retainer ring 48 to press a lower surface of the retainer ring 48 against the polishing surface 2a of the polishing pad 2.

The retainer-ring pressing mechanism 60 has an annular second elastic membrane 62 attached to the carrier 50. A second pressure chamber 65 is formed inside the second elastic membrane 62. The second pressure chamber 65 is coupled to the polishing-head pressure controller 33 through a second fluid line F4 and the rotary joint 22. When fluid (e.g., gas, such as air) is supplied to the second pressure chamber 65 through the second fluid line F4, the second elastic membrane 62 receives the fluid pressure in the second pressure chamber 65 to push the entirety of the retainer ring 48 downward. In this manner, the retainer-ring pressing mechanism 60 presses the lower surface of the retainer ring 48 against the polishing surface 2a of the polishing pad 2.

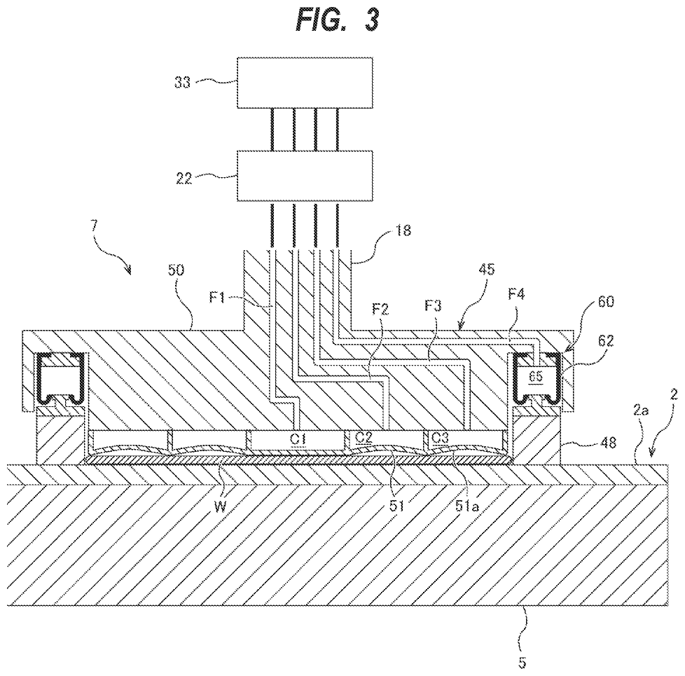

When a negative pressure is formed in any one of the first pressure chambers C1, C2, and C3 by the polishing-head pressure controller 33, the workpiece W is held on the pressing surface 51a of the first elastic membrane 51 by vacuum suction. For example, as shown in FIG. 3, when a negative pressure is formed in the first pressure chambers C2 and C3, the pressing surface 51a of the first elastic membrane 51 is depressed upward, and the first elastic membrane 51 acts as a suction cup that attracts the workpiece W. When the workpiece W is to be attracted to the first elastic membrane 51, a negative pressure may be formed in only one of the first pressure chambers C1, C2, C3, or all of the first pressure chambers C1, C2, C3.

In one embodiment, the pressing surface 51a of the first elastic membrane 51 may have a through-hole (not shown) communicating with at least one of the first pressure chambers C1, C2, C3. In this case, when a negative pressure is formed in the first pressure chamber communicating with the through-hole, a negative pressure is also formed in the through-hole, and this negative pressure can attract the workpiece W to the pressing surface 51a of the first elastic membrane 51.

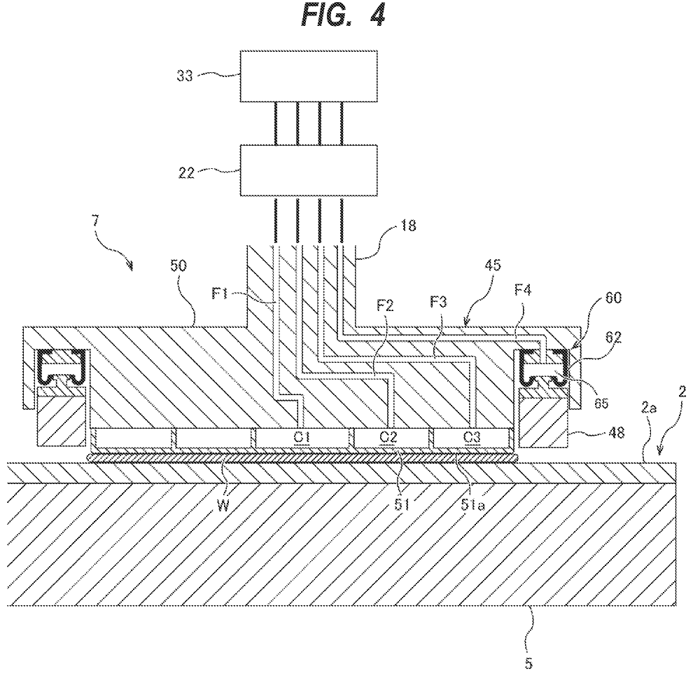

As shown in FIG. 4, when a negative pressure is formed in the second pressure chamber 65 by the polishing-head pressure controller 33, the retainer ring 48 is raised relative to the first elastic membrane 51, the carrier 50, and the workpiece W, and leaves the polishing pad 2. On the other hand, when the pressurized fluid is supplied into the second pressure chamber 65 by the polishing-head pressure controller 33, the retainer ring 48 is lowered relative to the first elastic membrane 51, the carrier 50, and the workpiece W and presses the polishing pad 2, as shown in FIG. 2. In this manner, the polishing-head pressure controller 33 can move the retainer ring 48 up and down by changing the pressure in the second pressure chamber 65.

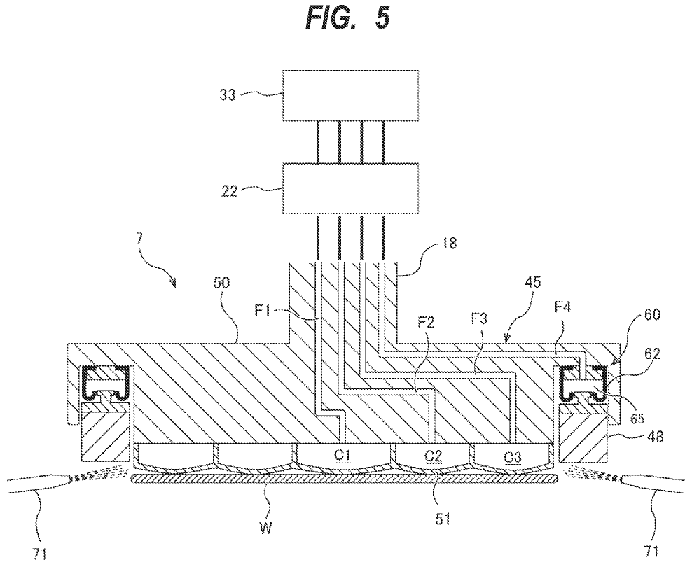

FIG. 5 is a diagram for explaining a manner in which the polished workpiece W is released from the polishing head 7. After polishing of the workpiece W, the polishing head 7 is moved together with the workpiece W to a workpiece transfer position. At this workpiece transfer position, fluid (e.g., gas, such as air) is supplied into the first pressure chambers C1, C2, and C3 to inflate the first elastic membrane 51. Then, a jet of release fluid (e.g., pure water, gas, or a mixture thereof) is emitted from release nozzles 71 to a contact portion between the workpiece W and the first elastic membrane 51, so that the workpiece W is released from the polishing head 7. When the workpiece W is released, as shown in FIG. 5, the retainer ring 48 is located higher than the workpiece W. Therefore, the release fluid can reach the contact portion between the workpiece W and the first elastic membrane 51. The released workpiece W is received by a transporting device (not shown) and transported for the next process.

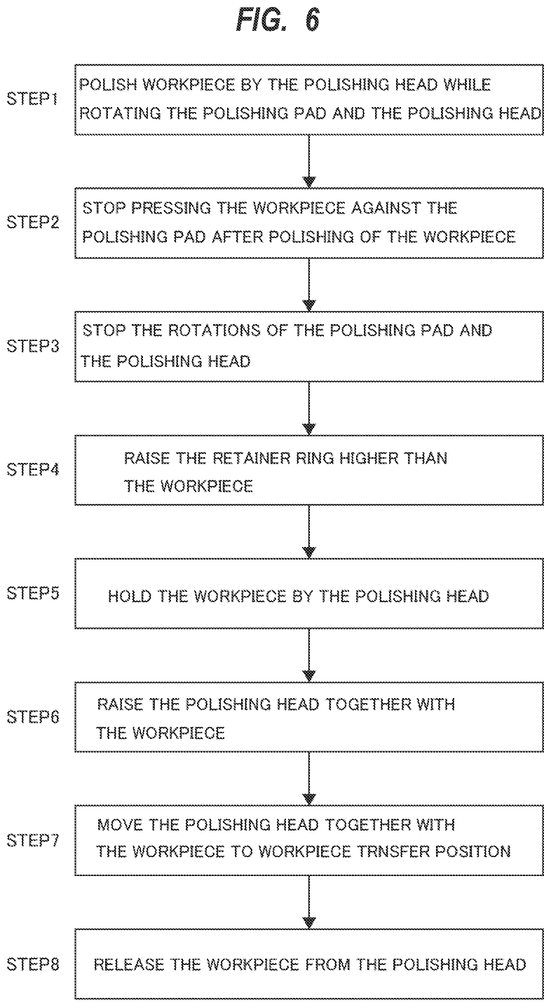

Next, operations of the polishing head 7 during and after polishing of the workpiece W will be described with reference to FIG. 6. FIG. 6 is a flow chart describing one embodiment of the operations of the polishing head 7 during and after polishing of the workpiece W.

In step 1, the operation controller 40 instructs the polishing-table rotating device 30 and the polishing-head rotating device 20 to rotate the polishing pad 2 and the polishing head 7 at predetermined speeds, respectively. The polishing liquid is supplied from the polishing-liquid supply nozzle 8 onto the rotating polishing pad 2. The operation controller 40 instructs the polishing-head elevating device 25 to lower the polishing head 7 to the predetermined polishing-operation height. The operation controller 40 further instructs the polishing-head pressure controller 33 to supply the pressurized fluid to the first pressure chambers C1, C2, C3 and the second pressure chamber 65 of the polishing head 7, so that the workpiece W and the retainer ring 48 are pressed against the polishing surface 2a of the polishing pad 2 (see FIG. 2). The workpiece W is placed in sliding contact with the polishing surface 2a of the polishing pad 2 in the presence of the polishing liquid on the polishing pad 2.

The surface of the workpiece W is polished by the combination of the chemical action of the polishing liquid and the mechanical action of the abrasive grains contained in the polishing liquid and/or the polishing pad 2. During polishing of the workpiece W, the polishing pad 2 rotates together with the polishing table 5, and the workpiece W rotates together with the polishing head 7. During the polishing of the workpiece W, the polishing head 7 is maintained at the polishing-operation height. This polishing-operation height is a relative height of the entire polishing head 7 with respect to the polishing surface 2a of the polishing pad 2.

In step 2, after the polishing of the workpiece W is terminated, the polishing head 7 stops pressing the workpiece W against the polishing pad 2. After the polishing of the workpiece W is terminated, the supply of the polishing liquid to the polishing pad 2 is also stopped.

In step 3, the operation controller 40 instructs the polishing-table rotating device 30 and the polishing-head rotating device 20 to stop the rotations of the polishing pad 2 and the polishing head 7. The polishing-table rotating device 30 stops the rotation of the polishing pad 2 by stopping the rotation of the polishing table 5.

In step 4, the operation controller 40 instructs the polishing-head pressure controller 33 to raise the retainer ring 48 relative to the workpiece W to separate the retainer ring 48 from the polishing pad 2 until the retainer ring 48 is moved to a position higher than the workpiece W (see FIG. 4). When the retainer ring 48 is being raised relative to the workpiece W, the rotations of the polishing pad 2 and the polishing head 7 have already been stopped. Therefore, the workpiece W does not come off the polishing head 7, and the relative position of the workpiece W with respect to the polishing head 7 does not change. While the retainer ring 48 is being raised relative to the workpiece W, the polishing head 7 is maintained at the polishing-operation height, and the workpiece W is in contact with the polishing pad 2.

In step 5, the operation controller 40 instructs the polishing-head pressure controller 33 to cause the polishing head 7 to hold the workpiece W. More specifically, a negative pressure is formed in at least one of the first pressure chambers C1 to C3 of the polishing head 7 so that the workpiece W is attracted to the pressing surface 51a of the first elastic membrane 51 by vacuum suction. At this time, at least part of the workpiece W is slightly pulled up from the polishing pad 2.

In step 6, the operation controller 40 instructs the polishing-head elevating device 25 to raise the entire polishing head 7 holding the workpiece W. The polishing head 7 is raised together with the workpiece W to a position higher than the polishing-operation height. The rotations of the polishing pad 2 and the polishing head 7 have already been stopped when the polishing head 7 and the workpiece W are being raised.

In step 7, the operation controller 40 instructs the polishing-head moving device 37 to rotate the polishing-head oscillation arm 16 about the support shaft 14 to move the polishing head 7 and the workpiece W to the predetermined workpiece transfer position.

In step 8, at the workpiece transfer position, a jet of the release fluid (e.g., pure water, gas, or a mixture thereof) is emitted from the release nozzles 71 to the contact portion between the workpiece W and the first elastic membrane 51 (see FIG. 5), thereby releasing the workpiece W from the polishing head 7.

According to the embodiment shown in FIG. 6, the retainer ring 48 is raised higher than the workpiece W (see FIG. 4) before the polishing head 7 is raised from the polishing pad 2. Therefore, when the polishing head 7 is raised, the workpiece W does not come into contact with the retainer ring 48, and the workpiece W is not bent downward by the retainer ring 48. As a result, an excessive stress is not generated in the workpiece W, and cracking of the workpiece W can be prevented.

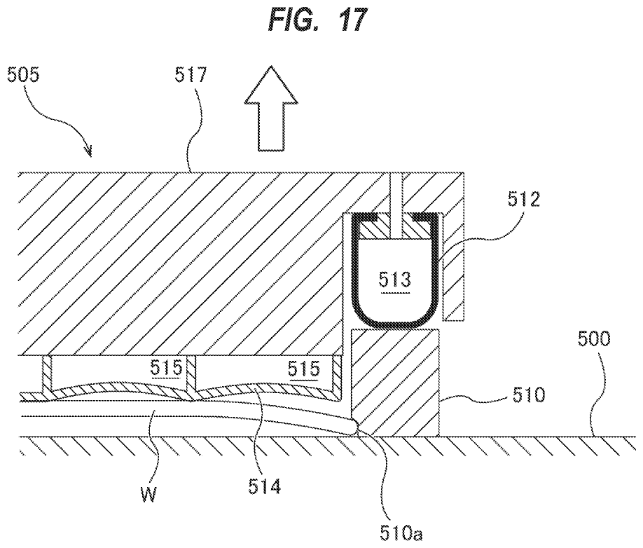

In the embodiment shown in FIG. 6, the retainer ring 48 is raised in the step 4 and then the workpiece W is held by the polishing head 7 in the step 5, while in one embodiment, the raising of the retainer ring 48 in the step 4 and the holding of the workpiece W by the polishing head 7 in the step 5 may be performed simultaneously. Further, in another embodiment, the workpiece W may be held by the polishing head 7 in step 4, and then the retainer ring 48 may be raised in step 5. However, as described with reference to FIG. 17, when a wear groove is formed in the inner surface of the retainer ring 48 due to contact with the workpiece W, the order of the step 4 and the step 5 shown in FIG. 6 is preferred. This is because, when the workpiece W is held by the polishing head 7, the first pressure chamber C3 is contracted due to the negative pressure, the workpiece W is slightly raised, the peripheral edge of the workpiece W may be caught by the wear groove, and the workpiece may bend.

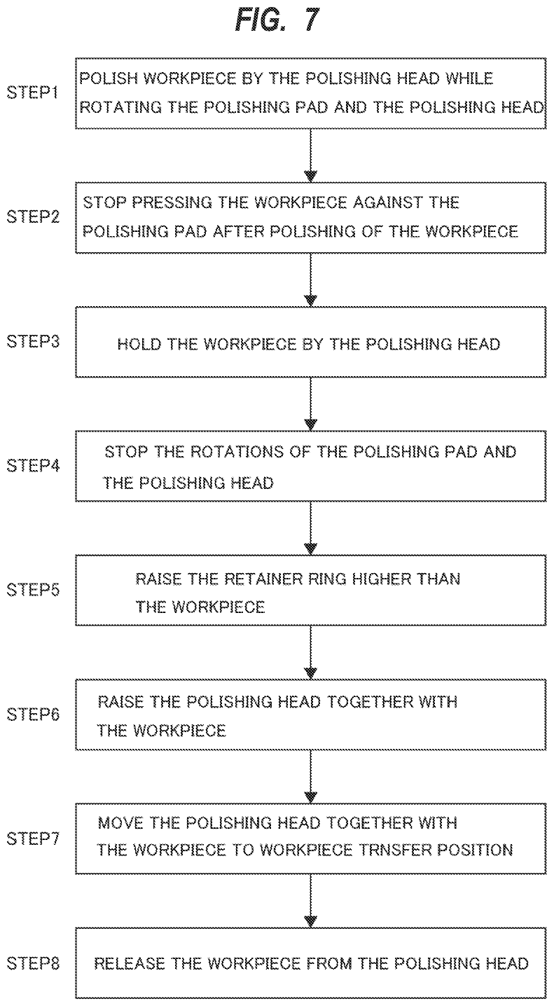

FIG. 7 is a flow chart describing another embodiment of the operations of the polishing head 7 during and after polishing of the workpiece W. Operations of each step, which will not be particularly described, are the same as the operations of each step described with reference to FIG. 6, and redundant descriptions thereof will be omitted.

As shown in FIG. 7, in this embodiment, in step 3, the polished workpiece W is held by the polishing head 7, and then in step 4, the rotations of the polishing pad 2 and polishing table 5 are stopped. Further, in step 5, the retainer ring 48 is raised to a position higher than the workpiece W. During the steps 3 and 4, the retainer ring 48 remains in contact with the polishing pad 2.

In the embodiment shown in FIG. 7, when the workpiece W is to be held by the polishing head 7, the polishing pad 2 and the polishing table 5 are rotating. Therefore, it is advantageous that the intimate contact between the workpiece W and the polishing head 7 is reduced by the liquid or air entering a space between the workpiece W and the polishing head 7, and the operation of attracting the workpiece W to the pressing surface 51a of the polishing head 7 can be ensured. On the other hand, if the inner surface of the retainer ring 48 has the wear groove caused by the contact with the workpiece W, the embodiment shown in FIG. 6 is preferable for the reason described above.

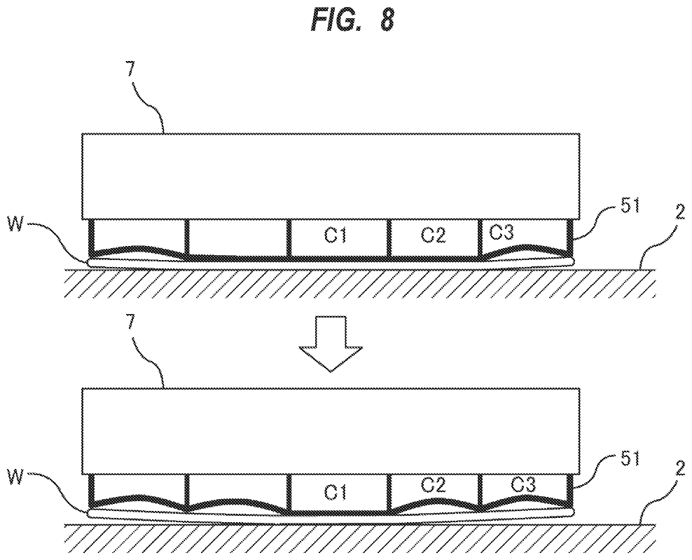

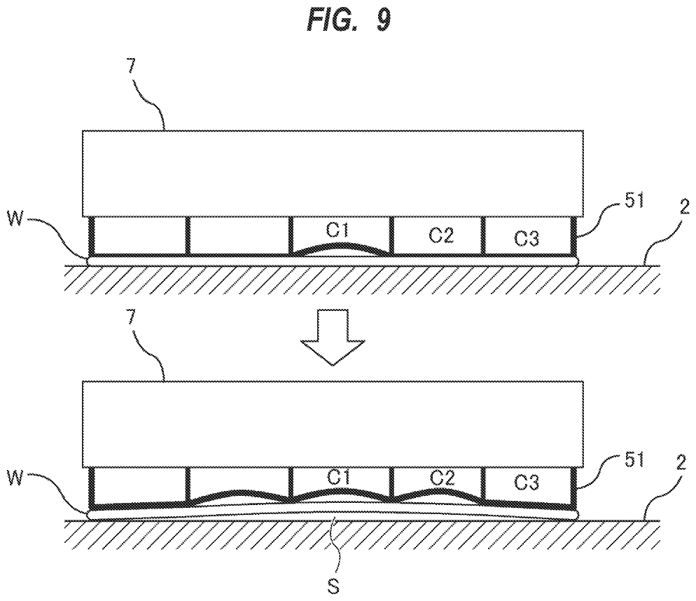

FIGS. 8 and 9 are schematic diagrams each showing an example of the operations of holding the workpiece W by the polishing head 7. In FIGS. 8 and 9, the polishing head 7 is depicted in a simplified manner and deformation of the workpiece W is depicted exaggeratedly. In the example shown in FIG. 8, negative pressure is formed in the order from the outer pressure chamber of the plurality of first pressure chambers C1 to C3. Specifically, a negative pressure is first formed in the outer first pressure chamber C3, and then a negative pressure is formed in the inner first pressure chamber C2. By forming the negative pressure in the first pressure chambers C3 and C2 in this order, the outer portion of the workpiece W is slightly raised by the first elastic membrane 51, and an open gap is formed between the outer portion of the workpiece W and the polishing pad 2.

In contrast, in the example shown in FIG. 9, the negative pressure is formed in the order from the inner pressure chamber of the plurality of first pressure chambers C1 to C3. Specifically, a negative pressure is first formed in the innermost first pressure chamber C1, and then a negative pressure is formed in the outer first pressure chamber C2. When negative pressure is formed in the first pressure chambers C1 and C2 in this order, the central portion of the workpiece W is slightly raised by the first elastic membrane 51, and a closed space S is formed between the central portion of the workpiece W and the polishing pad 2. Since the negative pressure is formed in this closed space S, the entire workpiece W functions as a suction cup, which prevents the workpiece W from being held by the polishing head 7.

From the above reason, it is preferable to first create a negative pressure in the outer first pressure chamber C3 and then create a negative pressure in the inner first pressure chamber C2. Such operations of holding the workpiece W allow the polishing head 7 to hold the workpiece W smoothly.

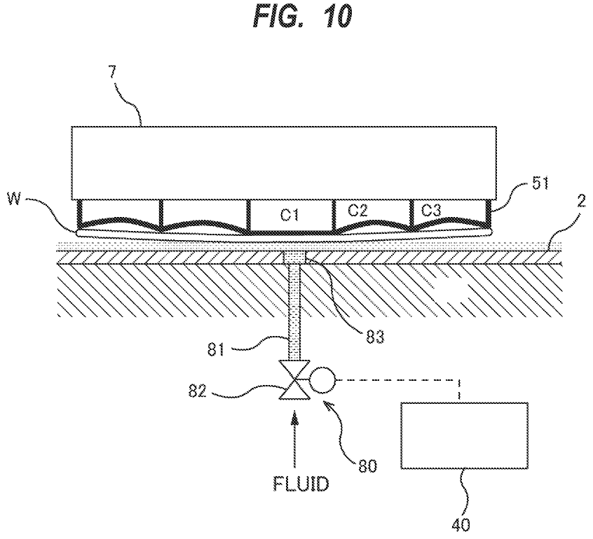

In one embodiment, as shown in FIG. 10, fluid may be supplied between the workpiece W and the polishing pad 2 when the polishing head 7 is holding the workpiece W. More specifically, the polishing apparatus includes a fluid supply system 80 configured to supply the fluid to an area between the workpiece W and the polishing pad 2. The fluid supply system 80 includes a fluid line 81 for supplying the fluid (e.g., liquid, or gas, or a mixture thereof) to the polishing surface 2a of the polishing pad 2, and an actuator-driven valve 82 coupled to the fluid line 81.

The fluid line 81 extends through the polishing table 5, and the fluid flows through an opening 83 formed in the polishing pad 2 onto the polishing surface 2a of the polishing pad 2. Examples of the actuator-driven valve 82 include motor-operated valve, solenoid valve, air-operated valve, and the like. The actuator-driven valve 82 is electrically coupled to the operation controller 40 so that operation of the actuator-driven valve 82 is controlled by the operation controller 40.

The operation controller 40 instructs the polishing-head pressure controller 33 to cause the polishing head 7 to hold the workpiece W, while the operation controller 40 instructs the fluid supply system 80 to supply the fluid to an area between the workpiece W and the polishing pad 2. With such operations, the workpiece W is held by the polishing head 7 while the fluid flows through the gap between the workpiece W and the polishing pad 2. The flow of the fluid in the gap between the workpiece W and the polishing pad 2 reduces the surface tension of the liquid acting between the workpiece W and the polishing pad 2. As a result, the polishing head 7 can hold the workpiece W reliably.

In one embodiment, while the polishing head 7 is being raised with the workpiece W from the polishing pad 2, the operation controller 40 may instruct the fluid supply system 80 to supply the fluid to the gap between the workpiece W and the polishing pad 2. The flow of the fluid in the gap between the workpiece W and the polishing pad 2 reduces the surface tension of the liquid acting between the workpiece W and the polishing pad 2. As a result, the polishing head 7 can smoothly separate the workpiece W from the polishing pad 2 when the polishing head 7 is raised.

In the step 6 described with reference to FIGS. 6 and 7, the polishing head 7 is raised together with the workpiece W while the retainer ring 48 is positioned higher than the workpiece W. At this time, although the workpiece W is held by the polishing head 7, part of the workpiece W may be in contact with the polishing pad 2. If part of the workpiece W is in contact with the polishing pad 2 when the polishing head 7 is raised together with the workpiece W, the surface tension of the liquid existing between the workpiece W and the polishing pad 2 may cause deformation of the workpiece W and an excessive stress may be applied to the workpiece W.

Thus, in one embodiment described below, the polishing head 7 is raised at a first speed until the entire workpiece W is separated from the polishing pad 2, and after the entire workpiece W is separated from the polishing pad 2, the polishing head 7 is raised at a second speed higher than the first speed.

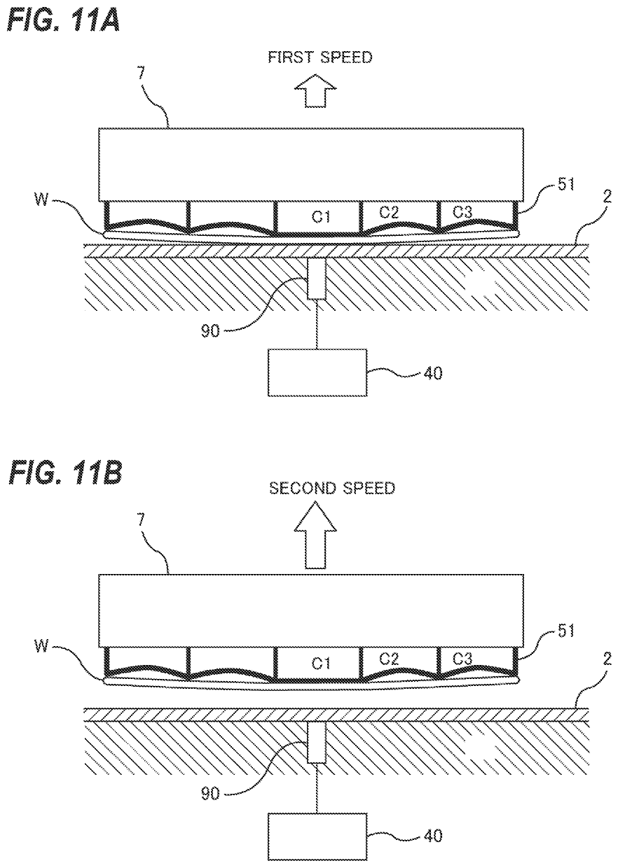

FIGS. 11A and 11B are schematic diagrams illustrating an embodiment in which the raising speed of the polishing head 7 is switched from the first speed to the second speed. The polishing head 7 is depicted in a simplified manner in FIGS. 11A and 11B. The polishing apparatus includes a workpiece detector 90 configured to detect a point in time at which the workpiece W is separated from the polishing pad 2. This workpiece detector 90 is arranged in the polishing table 5.

Configuration of the workpiece detector 90 is not particularly limited as long as the workpiece detector 90 can detect a point in time at which the workpiece W is separated from the polishing pad 2. The workpiece detector 90 may be a known sensor. For example, the workpiece detector 90 may be a displacement sensor configured to detect a displacement of the workpiece W, or may be a film-thickness sensor configured to detect a thickness of a film on the workpiece W (e.g., an eddy current sensor or an optical film-thickness sensor). In another example, the workpiece detector 90 may be configured to detect a point in time at which the workpiece W is separated from polishing pad 2 based on a change in pressure or flow rate of the fluid flowing from the opening in the polishing pad 2 to the gap between polishing pad 2 and the workpiece W.

As shown in FIG. 11A, the operation controller 40 instructs the polishing-head elevating device 25 (see FIG. 1) to raise the polishing head 7 at a first speed until the entire workpiece W is separated from the polishing pad 2. When the operation controller 40 receives a signal indicating that the entire workpiece W is separated from the polishing pad 2 from the workpiece detector 90, the operation controller 40 instructs the polishing-head elevating device 25 (see FIG. 1) to raise the polishing head 7 at a second speed higher than the first speed, as shown in FIG. 11B.

Such operations can reduce the stress on the workpiece W until the workpiece W is separated from the polishing pad 2. After the workpiece W is separated from the polishing pad 2, the polishing head 7 is raised rapidly, so that a throughput can be improved.

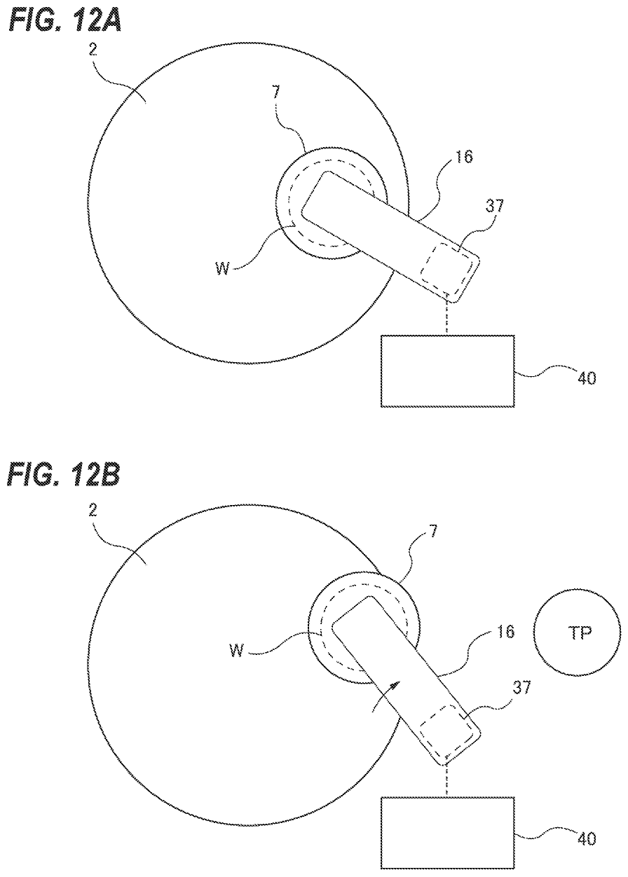

FIGS. 12A and 12B are plan views illustrating still another embodiment of the operations of the polishing head 7 after polishing the workpiece W. Operations of this embodiment, which will not be particularly described, are the same as the operations of the embodiments described with reference to FIGS. 6 and 7, and redundant descriptions thereof will be omitted.

In this embodiment, after polishing of the workpiece W, the polishing head 7 is moved from a polishing position shown in FIG. 12A to an overhanging position shown in FIG. 12B. More specifically, after polishing of the workpiece W, while the polishing pad 2 and the polishing head 7 are rotating, the operation controller 40 instructs the polishing-head moving device 37 to move the polishing head 7 from the polishing position shown in FIG. 12A to the overhanging position shown in FIG. 12B. The overhanging position is a position where a portion of the workpiece W held by the polishing head 7 protrudes radially outward from the polishing pad 2.

The operation of moving the polishing head 7 to the overhanging position is performed after polishing of the workpiece W and before the workpiece W is held by the polishing head 7. For example, in the flow chart shown in FIG. 6, the operation of moving the polishing head 7 to the overhanging position is performed after the pressing of the workpiece W against the polishing pad 2 is stopped in step 2 and before the rotations of the polishing pad 2 and the polishing table 5 are stopped in step 3. In the flow chart shown in FIG. 7, the operation of moving the polishing head 7 to the overhanging position is performed after the pressing of the workpiece W against the polishing pad 2 is stopped in step 2 and before the workpiece W is held by the polishing head 7 in step 3.

At the overhanging position, a part of the workpiece W is located outside the polishing head 7, so that the surface tension of the liquid acting between the workpiece W and the polishing pad 2 is reduced. Therefore, the polishing head 7 can hold the workpiece W reliably.

After the polishing head 7 is raised together with the workpiece W from the polishing pad 2, the operation controller 40 instructs the polishing-head moving device 37 to move the polishing head 7 and the workpiece W to a workpiece transfer position TP shown in FIG. 12B. At this workpiece transfer position TP, as described with reference to FIG. 5, a jet of the release fluid (e.g., pure water, gas, or a mixture thereof) is emitted from the release nozzles 71 to the contact portion between the workpiece W and the polishing head 7, so that the workpiece W is released from the polishing head 7.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A method of raising a polishing head after polishing of a workpiece, comprising:
polishing the workpiece by pressing the workpiece against a polishing pad while rotating the polishing head and the polishing pad;
stopping the rotations of the polishing pad and the polishing head;
raising a retainer ring of the polishing head relative to the workpiece to separate the retainer ring from the polishing pad and moving the retainer ring to a position higher than the workpiece; and then
raising the polishing head with the workpiece held on the polishing head.

2. The method according to claim 1, further comprising holding the workpiece by the polishing head after polishing of the workpiece and before raising of the polishing head.

3. The method according to claim 2, wherein raising the retainer ring to the position higher than the workpiece is performed before or simultaneously with holding the workpiece by the polishing head.

4. The method according to claim 2, wherein holding the workpiece by the polishing head is performed while supplying fluid directly to an area between the workpiece and the polishing pad.

5. The method according to claim 2, wherein the polishing head includes an elastic membrane forming a plurality of pressure chambers for pressing the workpiece against the polishing pad,
holding the workpiece by the polishing head comprises holding the workpiece with the polishing head by forming a negative pressure in an outer pressure chamber of the plurality of pressure chambers and then forming a negative pressure in an inner pressure chamber of the plurality of pressure chambers.

6. The method according to claim 2, wherein holding the workpiece by the polishing head is performed before stopping the rotations of the polishing pad and the polishing head.

7. The method according to claim 1, wherein raising the polishing head comprises: raising the polishing head at a first speed until the entire workpiece is separated from the polishing pad; and raising the polishing head at a second speed higher than the first speed after the entire workpiece is separated from the polishing pad.

8. A polishing apparatus for a workpiece, comprising:
a polishing table configured to support a polishing pad;
a polishing-table rotating device configured to rotate the polishing table together with the polishing pad;
a polishing head configured to press the workpiece against the polishing pad to polish the workpiece;
a polishing-head pressure controller configured to control pressure in the polishing head;
a polishing-head rotating device configured to rotate the polishing head;
a polishing-head elevating device configured to raise and lower the polishing head relative to the polishing table; and
an operation controller configured to control operations of the polishing-table rotating device, the polishing-head pressure controller, the polishing-head rotating device, and the polishing-head elevating device,
the polishing head having a retainer ring surrounding the workpiece,
the operation controller being configured to:
after polishing of the workpiece, instruct the polishing-table rotating device and the polishing-head rotating device to stop rotations of the polishing pad and the polishing head;
instruct the polishing-head pressure controller to raise the retainer ring relative to the workpiece to separate the retainer ring from the polishing pad and move the retainer ring to a position higher than the workpiece; and then
instruct the polishing-head elevating device to raise the polishing head with the workpiece held on the polishing head.

9. The polishing apparatus according to claim 8, wherein the operation controller is configured to instruct the polishing-head pressure controller to cause the polishing head to hold the workpiece after the workpiece is polished and before the polishing head is raised.

10. The polishing apparatus according to claim 9, wherein the operation controller is configured to instruct the polishing-head pressure controller to raise the retainer ring to the position higher than the workpiece before or simultaneously with the workpiece is held by the polishing head.

11. The polishing apparatus according to claim 9, further comprising a fluid supply system configured to supply fluid to an area between the workpiece and the polishing pad, the operation controller being configured to instruct the fluid supply system to supply the fluid directly to the area between the workpiece and the polishing pad when the polishing head holds the workpiece.

12. The polishing apparatus according to claim 9, wherein the polishing head includes an elastic membrane forming a plurality of pressure chambers for pressing the workpiece against the polishing pad, and
the operation controller is configured to instruct the polishing-head pressure controller to cause the polishing head to hold the workpiece by forming a negative pressure in an outer pressure chamber of the plurality of pressure chambers and then forming a negative pressure in an inner pressure chamber of the plurality of pressure chambers.

13. The polishing apparatus according to claim 9, wherein the operation controller is configured to instruct the polishing-head pressure controller to cause the polishing head to hold the workpiece before rotations of the polishing pad and the polishing head are stopped.

14. The polishing apparatus according to claim 8, wherein the operation controller is configured to instruct the polishing-head elevating device to raise the polishing head at a first speed until the entire workpiece is separated from the polishing pad, and raise the polishing head at a second speed higher than the first speed after the entire workpiece is separated from the polishing pad.

15. A computer-readable storage medium storing a program for causing a computer to:
instruct a polishing-head pressure controller, a polishing-table rotating device, and a polishing-head rotating device to polish a workpiece by pressing the workpiece against a polishing pad while rotating a polishing head and the polishing pad on a polishing table;
after polishing of the workpiece, instruct the polishing-table rotating device and the polishing-head rotating device to stop the rotations of the polishing pad and the polishing head;
instruct the polishing-head pressure controller to raise a retainer ring of the polishing head relative to the workpiece to separate the retainer ring from the polishing pad and move the retainer ring to a position higher that the workpiece; and
instruct the polishing-head elevating device to raise the polishing head with the workpiece held on the polishing head.
